(19) United States
(12) Patent Application Publication
(10) Pub. No.: US 2026/0173388 A1
(43) Pub. Date: Jun. 18, 2026

(54) PERIPHERAL CIRCUIT SYSTEM OF MEMORY DEVICE AND MEMORY DEVICE

(71) Applicant: MACRONIX INTERNATIONAL CO., LTD., Hsinchu (TW)

(72) Inventor: Shih-Hung CHEN, Taoyuan City (TW)

(21) Appl. No.: 18/978,026

(22) Filed: Dec. 12, 2024

(51) Int. Cl. H10B 43/40; H10B 41/41

(52) U.S. Cl. CPC H10B 43/40; H10B 41/41

(57) ABSTRACT

A peripheral circuit system of a memory device and a memory device are provided. The peripheral circuit system of a memory device includes a first peripheral circuit electrically connected to a memory array of the memory device, and a second peripheral circuit electrically connected to the memory array. The first peripheral circuit and the second peripheral circuit are arranged along a longitudinal direction.

### BACKGROUND

### Technical Field

The present disclosure relates to a peripheral circuit system of a memory device and a memory device.

### Description of the Related Art

Memory devices includes a memory array for data storage and a peripheral circuit system for controlling the memory array. Increasing the footprint of the peripheral circuit system usually improves the performance, endurance, power consumption, and reliability of the memory device. However, increasing the footprint of peripheral circuit system adversely affects area shrinkage of memory device.

### SUMMARY

The present disclosure relates to a peripheral circuit system of a memory device and a memory device, which can increase the footprint of the peripheral circuit system without increasing the area of the memory device. The performance, endurance, power consumption, and reliability of the memory device can be improved.

According to embodiments of the present disclosure, a peripheral circuit system of a memory device is provided. The peripheral circuit system includes a first peripheral circuit electrically connected to a memory array of the memory device, and a second peripheral circuit electrically connected to the memory array. The first peripheral circuit and the second peripheral circuit are arranged along a longitudinal direction.

According to embodiments of the present disclosure, a memory device is provided. The memory device includes a first semiconductor structure including a first peripheral circuit, and a second semiconductor structure including a second peripheral circuit and a memory array. The first semiconductor structure is bonded to the second semiconductor structure. The first peripheral circuit is electrically connected to the memory array. The second peripheral circuit is electrically connected to the memory array.

According to embodiments of the present disclosure, a memory device is provided. The memory device includes a first semiconductor structure including a first peripheral circuit, a second semiconductor structure including a second peripheral circuit, and a third semiconductor structure including a memory array. The first semiconductor structure, the second semiconductor structure, and the third semiconductor structure are arranged along a longitudinal direction. The first peripheral circuit is electrically connected to the memory array. The second peripheral circuit is electrically connected to the memory array.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a memory device according to some embodiments of the present disclosure.

FIG. 2 illustrates a schematic view of a memory device according to some embodiments of the present disclosure.

FIG. 3 illustrates a schematic view of a memory device according to some embodiments of the present disclosure.

FIG. 4 illustrates a schematic view of a memory device according to some embodiments of the present disclosure.

FIG. 5 illustrates a schematic cross-sectional view of a memory device according to some embodiments of the present disclosure.

FIG. 6 illustrates a schematic cross-sectional view of a memory device according to some embodiments of the present disclosure.

FIG. 7 illustrates a schematic cross-sectional view of a memory device according to some embodiments of the present disclosure.

FIG. 8 illustrates a schematic cross-sectional view of a memory device according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. The term “functional surface” used in the specification and claims can refer to a surface on which electronic components, such as transistors, diodes, resistors, or capacitors, are formed.

The term “interconnection structure” used in the specification and claims can broadly include any suitable type of interconnection structure, such as an interconnection structure formed in a mid-end of line (MEOL) process, or an interconnection structure formed in a back end of line (BEOL) process. The interconnection structure can include one or more lateral interconnection lines and/or one or more longitudinal interconnection vias. The interconnection line and interconnection via may include conductive materials, including but not limited to tungsten, cobalt, copper, aluminum, silicide, or any combination thereof. In addition, the interconnection structure may include one or more interlayer dielectric layers. The interconnection lines and the interconnection vias may be formed in the interlayer dielectric layers. The interlayer dielectric layers may include dielectric materials, including but not limited to silicon oxide, silicon nitride, silicon oxynitride, low-k dielectric materials, or any combination thereof.

Embodiments according to the present disclosure can be applied to many different types of memory devices. The memory devices may include a volatile memory array or a non-volatile memory array. In some embodiments, the present disclosure can be applied to vertical channel NAND type flash memory devices.

The memory device includes a memory array and a peripheral circuit system. The peripheral circuit system includes a first peripheral circuit electrically connected to the memory array and a second peripheral circuit electrically connected to the memory array. The memory array may include a plurality of memory strings. Each of the plurality of memory strings may include memory cells. The memory array can be used to store date. The first peripheral circuit and the second peripheral circuit can be used to control the memory cells of the memory array. For example, the first peripheral circuit and the second peripheral circuit can be used to reading, writing, or erasing memory cell. The first peripheral circuit and the second peripheral circuit may include different components, but the present disclosure is not limited thereto. In the present disclosure, the memory array, the first peripheral circuit and the second peripheral circuit are arranged along a longitudinal direction. The memory array, the first peripheral circuit and the second peripheral circuit can be stacked on top of one another in the longitudinal direction. The first peripheral circuit can be disposed above or below the second peripheral circuit in the longitudinal direction.

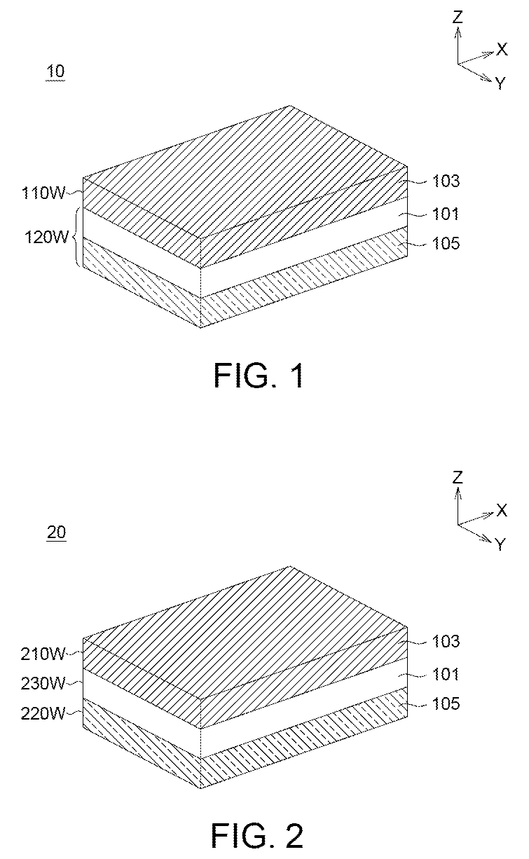

Referring to FIG. 1, FIG. 1 illustrates a schematic view of a memory device 10 according to some embodiments of the present disclosure. The memory device 10 includes a memory 101 and a peripheral circuit system. The peripheral circuit system includes a first peripheral circuit 103 and a second peripheral circuit 105. The first peripheral circuit 103 is electrically connected to the memory array 101. The second peripheral circuit 105 is electrically connected to the memory array 101. The first peripheral circuit 103 can be electrically connected to the second peripheral circuit 105. The first peripheral circuit 103 is disposed above the memory array 101 in a Z direction (e.g. a longitudinal direction). The second peripheral circuit 105 is disposed below the first peripheral circuit 103 in the Z direction. The second peripheral circuit 105 is disposed below the memory array 101 in the Z direction. The first peripheral circuit 103 and the second peripheral circuit 105 are disposed on opposite sides of the memory array 101. The first peripheral circuit 103 includes a high-speed drive circuit. The high-speed drive circuit includes at least one page buffer and at least one input/output circuit. The second peripheral circuit 105 includes a high-voltage drive circuit. The high-voltage drive circuit includes at least one charge pumping circuit and at least one row decoder.

The first peripheral circuit 103 is disposed in a first semiconductor structure 110W. The memory array 101 and the second peripheral circuit 105 are disposed in a second semiconductor structure 120W. In an embodiment, the second semiconductor structure 120W includes a substrate, the second peripheral circuit 105 can be formed on a first side of the substrate, and then the memory array 101 can be formed on a second side of the substrate opposite to the first side. The first semiconductor structure 110W and the second semiconductor structure 120W are arranged along the Z direction. The first semiconductor structure 110W and the second semiconductor structure 120W can be stacked on top of one another in the Z direction. The first semiconductor structure 110W is stacked above the second semiconductor structure 120W in the Z direction. The first semiconductor structure 110W is hybrid bonded to the second semiconductor structure 120W. The first semiconductor structure 110W has a functional surface and a back surface opposite to the functional surface. The second semiconductor structure 120W has a functional surface and a back surface opposite to the functional surface. The first semiconductor structure 110W is bonded to the second semiconductor structure 120W in a face-to-face orientation. The functional surface of the first semiconductor structure 110W is bonded to the functional surface of the second semiconductor structure 120W. The first semiconductor structure 110W and the second semiconductor structure 120W can be different semiconductor wafers or chips.

Referring to FIG. 2, FIG. 2 illustrates a schematic view of a memory device 20 according to some embodiments of the present disclosure. The differences between the memory device 20 and the memory device 10 shown in FIG. 1 are that the memory array and the peripheral circuit system of the memory device 20 are disposed in three semiconductor structures (first semiconductor structure, second semiconductor structure and third semiconductor structure). The memory device 20 includes a memory 101 and a peripheral circuit system. The peripheral circuit system includes a first peripheral circuit 103 and a second peripheral circuit 105. The first peripheral circuit 103 is electrically connected to the memory array 101. The second peripheral circuit 105 is electrically connected to the memory array 101. The first peripheral circuit 103 can be electrically connected to the second peripheral circuit 105. The first peripheral circuit 103 and the second peripheral circuit 105 are disposed on opposite sides of the memory array 101. The first peripheral circuit 103 is disposed above the memory array 101 and the second peripheral circuit 105 in the Z direction. The memory array 101 is disposed above the second peripheral circuit 105 in the Z direction.

The first peripheral circuit 103 is disposed in a first semiconductor structure 210W. The second peripheral circuit 105 is disposed in a second semiconductor structure 220W. The memory array 101 is disposed in a third semiconductor structure 230W. The first semiconductor structure 210W, the second semiconductor structure 220W and the third semiconductor structure 230W are arranged along the Z direction. The first semiconductor structure 210W, the second semiconductor structure 220W and the third semiconductor structure 230W can be stacked on top of one another in the Z direction. The third semiconductor structure 230W is disposed between the first semiconductor structure 210W and the second semiconductor structure 220W in the Z direction. The third semiconductor structure 230W is stacked above the second semiconductor structure 220W in the Z direction. The first semiconductor structure 210W is stacked above the third semiconductor structure 230W in the Z direction. The first semiconductor structure 210W is hybrid bonded to the third semiconductor structure 230W. The second semiconductor structure 220W is hybrid bonded to the third semiconductor structure 230W. The first semiconductor structure 210W has a functional surface and a back surface opposite to the functional surface. The second semiconductor structure 220W has a functional surface and a back surface opposite to the functional surface. The third semiconductor structure 230W has a functional surface and a back surface opposite to the functional surface. The first semiconductor structure 210W is bonded to the third semiconductor structure 230W in a face-to-face orientation. The second semiconductor structure 220W is bonded to the third semiconductor structure 230W in a face-to-back orientation. The functional surface of the first semiconductor structure 210W is bonded to the functional surface of the third semiconductor structure 230W. The back surface of the third semiconductor structure 230W is bonded to the functional surface of the second semiconductor structure 220W. The first semiconductor structure 210W, the second semiconductor structure 220W and the third semiconductor structure 230W can be different semiconductor wafers or chips.

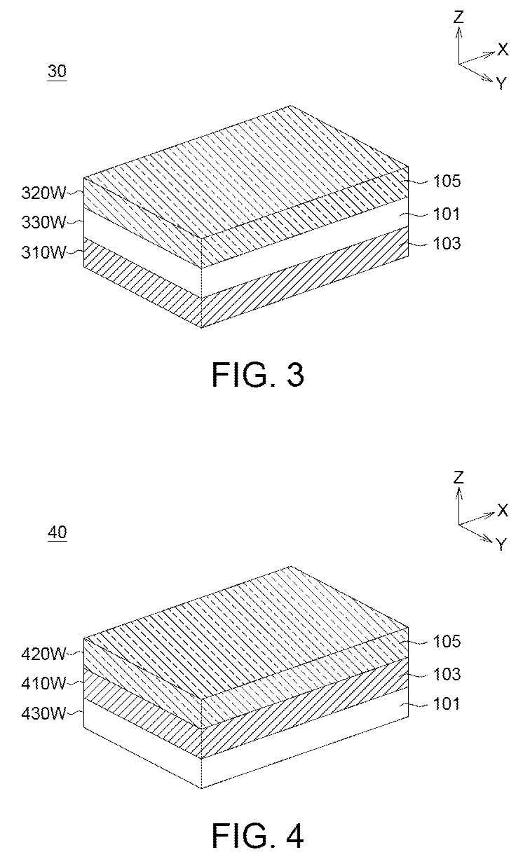

Referring to FIG. 3, FIG. 3 illustrates a schematic view of a memory device 30 according to some embodiments of the present disclosure. The differences between the memory device 30 and the memory device 20 shown in FIG. 2 are that the arrangement order of the first semiconductor structure, the second semiconductor structure and the third semiconductor structure of the memory device 30 is different from the arrangement order of the first semiconductor structure, the second semiconductor structure and the third semiconductor structure of the memory device 20, and the configuration of the memory array, the first peripheral circuit, and the second peripheral circuit of the memory device 30 is different from the configuration of the memory array, the first peripheral circuit, and the second peripheral circuit of the memory device 20. The memory device 30 includes a memory 101 and a peripheral circuit system. The peripheral circuit system includes a first peripheral circuit 103 and a second peripheral circuit 105. The first peripheral circuit 103 is electrically connected to the memory array 101. The second peripheral circuit 105 is electrically connected to the memory array 101. The first peripheral circuit 103 can be electrically connected to the second peripheral circuit 105. The first peripheral circuit 103 and the second peripheral circuit 105 are disposed on opposite sides of the memory array 101. The second peripheral circuit 105 is disposed above the memory array 101 and the first peripheral circuit 103 in the Z direction. The memory array 101 is disposed above the first peripheral circuit 103 in the Z direction.

The first peripheral circuit 103 is disposed in a first semiconductor structure 310W. The second peripheral circuit 105 is disposed in a second semiconductor structure 320W. The memory array 101 is disposed in a third semiconductor structure 330W. The first semiconductor structure 310W, the second semiconductor structure 320W and the third semiconductor structure 330W are arranged along the Z direction. The first semiconductor structure 310W, the second semiconductor structure 320W and the third semiconductor structure 330W can be stacked on top of one another in the Z direction. The third semiconductor structure 330W is disposed between the first semiconductor structure 310W and the second semiconductor structure 320W in the Z direction. The third semiconductor structure 330W is stacked above the first semiconductor structure 310W in the Z direction. The second semiconductor structure 320W is stacked above the third semiconductor structure 330W in the Z direction. The first semiconductor structure 310W is hybrid bonded to the third semiconductor structure 330W. The second semiconductor structure 320W is hybrid bonded to the third semiconductor structure 330W. The first semiconductor structure 310W has a functional surface and a back surface opposite to the functional surface. The second semiconductor structure 320W has a functional surface and a back surface opposite to the functional surface. The third semiconductor structure 330W has a functional surface and a back surface opposite to the functional surface. The second semiconductor structure 320W is bonded to the third semiconductor structure 330W in a face-to-face orientation. The first semiconductor structure 310W is bonded to the third semiconductor structure 330W in a face-to-back orientation. The functional surface of the third semiconductor structure 330W is bonded to the functional surface of the second semiconductor structure 320W. The functional surface of the first semiconductor structure 310W is bonded to the back surface of the third semiconductor structure 330W. The first semiconductor structure 310W, the second semiconductor structure 320W and the third semiconductor structure 330W can be different semiconductor wafers or chips.

Referring to FIG. 4, FIG. 4 illustrates a schematic view of a memory device 40 according to some embodiments of the present disclosure. The differences between the memory device 40 and the memory device 20 shown in FIG. 2 are that the arrangement order of the first semiconductor structure, the second semiconductor structure and the third semiconductor structure of the memory device 40 is different from the arrangement order of the first semiconductor structure, the second semiconductor structure and the third semiconductor structure of the memory device 20, and the configuration of the memory array, the first peripheral circuit, and the second peripheral circuit of the memory device 40 is different from the configuration of the memory array, the first peripheral circuit, and the second peripheral circuit of the memory device 20.

The memory device 40 includes a memory 101 and a peripheral circuit system. The peripheral circuit system includes a first peripheral circuit 103 and a second peripheral circuit 105. The first peripheral circuit 103 is electrically connected to the memory array 101. The second peripheral circuit 105 is electrically connected to the memory array 101. The first peripheral circuit 103 can be electrically connected to the second peripheral circuit 105. The second peripheral circuit 105 and the memory array 101 are disposed on opposite sides of the first peripheral circuit 103. The first peripheral circuit 103 and the second peripheral circuit 105 are disposed on the same side of the memory array 101. The second peripheral circuit 105 is disposed above the memory array 101 and the first peripheral circuit 103 in the Z direction. The first peripheral circuit 103 is disposed above the memory array 101 in the Z direction.

The first peripheral circuit 103 is disposed in a first semiconductor structure 410W. The second peripheral circuit 105 is disposed in a second semiconductor structure 420W. The memory array 101 is disposed in a third semiconductor structure 430W. The first semiconductor structure 410W, the second semiconductor structure 420W and the third semiconductor structure 430W are arranged along the Z direction. The first semiconductor structure 410W, the second semiconductor structure 420W and the third semiconductor structure 430W can be stacked on top of one another in the Z direction. The first semiconductor structure 410W is disposed between the third semiconductor structure 430W and the second semiconductor structure 420W in the Z direction. The second semiconductor structure 420W is stacked above the first semiconductor structure 410W in the Z direction. The first semiconductor structure 410W is stacked above the third semiconductor structure 430W in the Z direction. The first semiconductor structure 410W is hybrid bonded to the second semiconductor structure 420W. The first semiconductor structure 410W is hybrid bonded to the third semiconductor structure 430W. The first semiconductor structure 410W has a functional surface and a back surface opposite to the functional surface. The second semiconductor structure 420W has a functional surface and a back surface opposite to the functional surface. The third semiconductor structure 430W has a functional surface and a back surface opposite to the functional surface. The first semiconductor structure 410W is bonded to the second semiconductor structure 420W in a face-to-face orientation. The third semiconductor structure 430W is bonded to the first semiconductor structure 410W in a face-to-back orientation. The functional surface of the first semiconductor structure 410W is bonded to the functional surface of the second semiconductor structure 420W. The functional surface of the third semiconductor structure 430W is bonded to the back surface of the first semiconductor structure 410W. The first semiconductor structure 410W, the second semiconductor structure 420W and the third semiconductor structure 430W can be different semiconductor wafers or chips.

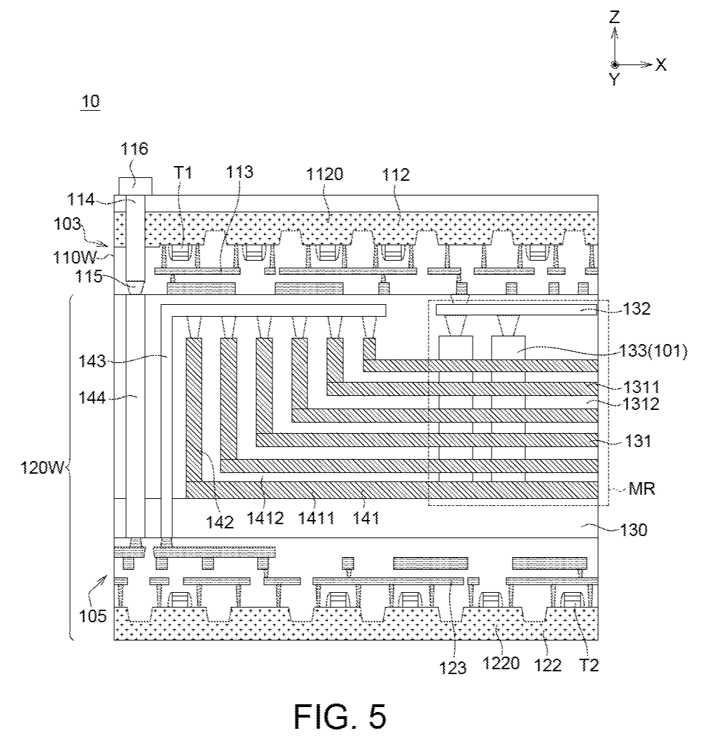

Referring to FIG. 5, FIG. 5 illustrates a schematic cross-sectional view showing one of the component configurations of the memory device 10 according to some embodiments of the present disclosure. The memory device 10 includes the first semiconductor structure 110W and the second semiconductor structure 120W. The first semiconductor structure 110W includes the first peripheral circuit 103. The first semiconductor structure 110W includes a device layer 112, an interconnection structure 113, a via element 114, a pad 115 and an input/output pad 116. The device layer 112 includes a semiconductor layer 1120 and transistors T1. The semiconductor layer 1120 may include a semiconductor material such as doped or undoped monocrystalline silicon, doped or undoped polycrystalline silicon, and germanium. FIG. 5 shows that the transistor T1 is on the surface of the semiconductor layer 1120, but the present disclosure is not limited thereto. The transistor T1 can be disposed near the surface of the semiconductor layer 1120, that is, the transistor T1 may be completely disposed above the surface of the semiconductor layer 1120; or alternatively, a portion of the transistor T1 (e.g. the gate structure) may be disposed above the surface of the semiconductor layer 1120, and another portion of the transistor T1 (e.g. the drain structure and/or source structure) may be disposed under the surface of the semiconductor layer 1120 and in the semiconductor layer 1120; or alternatively, the transistor T1 may be completely disposed in the semiconductor layer 1120. The interconnection structure 113 is disposed on a first side of the semiconductor layer 1120. The transistors T1 can be electrically connected to the interconnection structure 113. The interconnection structure 113 may include a conductive material. The via element 114 can penetrate the semiconductor layer 1120. The via element 114 may be disposed between the pad 115 and the input/output pad 116. The via element 114, the pad 115 and the input/output pad 116 can be electrically connected to each other. The via element 114 may include a conductive material. For example, the via element is a through silicon via (TSV) element. The pad 115 is disposed on the first side of the semiconductor layer 1120. The input/output pad 116 is disposed on a second side of the semiconductor layer 1120. The second side of the semiconductor layer 1120 is opposite to the first side of the semiconductor layer 1120. The pad 115 may include a conductive material. The input/output pad 116 may include a conductive material.

In the embodiment shown in FIG. 5, the surface including the pad 115 and the interconnection structure 113 can be defined as the functional surface of the first semiconductor structure 110W, and the surface including the input/output pad 116 can be defined as the back surface of the first semiconductor structure 110W. The device layer 112, the interconnection structure 113, the via element 114, the pad 115 and the input/output pad 116 can form a portion of the first peripheral circuit 103; or alternatively, the first peripheral circuit 103 can include the device layer 112, the interconnection structure 113, the via element 114, the pad 115 and the input/output pad 116. The input/output pad 116 can be a portion of the input/output circuit of the first peripheral circuit 103. The transistors T1 can be electrically connected to the page buffer of the first peripheral circuit 103 or can be a portion of the page buffer of the first peripheral circuit 103. The input/output pad 116 can be used to receive a voltage such as voltage V_{DD} or voltage V_{SS}.

In an embodiment, the transistor T1 can be a complementary metal-oxide-semiconductor (CMOS) field-effect transistor.

The semiconductor structure 120W includes the memory array 101 and the second peripheral circuit 105. The semiconductor structure 120W includes a device layer 122, an interconnection structure 123, a substrate 130, a stacked structure 131, a conductive element 132, memory strings 133, a stepped structure 141, plug elements 142, a conductive structure 143 and a contact element 144. The substrate 130 may include dielectric material. The device layer 122 includes a semiconductor layer 1220 and transistors T2. The semiconductor layer 1220, the transistors T2 and the interconnection structure 123 can be disposed on a first side of the substrate 130. The stacked structure 131, the conductive element 132, the memory strings 133, the stepped structure 141, the plug elements 142, the conductive structure 143 and the contact element 144 can be disposed on a second side of the substrate 130. The second side of the substrate 130 is opposite to the first side of the substrate 130.

The semiconductor layer 1220 may include a semiconductor material such as doped or undoped monocrystalline silicon, doped or undoped polycrystalline silicon, and germanium. FIG. 5 shows that the transistor T2 is on the surface of the semiconductor layer 1220, but the present disclosure is not limited thereto. The transistor T2 can be disposed near the surface of the semiconductor layer 1220, that is, the transistor T2 may be completely disposed above the surface of the semiconductor layer 1120; or alternatively, a portion of the transistor T2 (e.g. the gate structure) may be disposed above the surface of the semiconductor layer 1220, and another portion of the transistor T2 (e.g. the drain structure and/or source structure) may be disposed under the surface of the semiconductor layer 1220 and in the semiconductor layer 1220; or alternatively, the transistor T2 may be completely disposed in the semiconductor layer 1220. The interconnection structure 123 is disposed on the semiconductor layer 1220. The transistors T2 can be electrically connected to the interconnection structure 123. The interconnection structure 123 may include a conductive material. The device layer 122 and the interconnection structure 123 can form a portion of the second peripheral circuit 105; or alternatively, the second peripheral circuit 105 can include the device layer 122 and the interconnection structure 123. The transistors T2 can be electrically connected to the charge pumping circuit and the row decoder of the second peripheral circuit 105. In an embodiment, the transistors T2 can be a complementary metal-oxide-semiconductor field-effect transistor.

The stacked structure 131 and the memory strings 133 can be disposed in the array region MR of the second semiconductor structure 120W. The stacked structure 131 is disposed on the substrate 130. The stacked structure 131 can include conductive layers 1311 and insulating layers 1312 stacked alternately along the Z direction. The conductive layers 1311 are separated from each other by the insulating layers 1312. The conductive layers 1311 and the insulating layers 1312 can extend along the X direction (e.g. lateral direction) and/or the Y direction (e.g. lateral direction). The X direction, Y direction and Z direction are perpendicular to each other. The conductive layer 1311 may include a conductive material, and the conductive material includes, but not limited to, doped or undoped polycrystalline silicon, metal, or combinations thereof. The insulating layer 1312 may include an insulating material, and the insulating material includes, but not limited to, silicon oxide. The memory strings 133 are disposed on the substrate 130. The memory strings 133 are disposed separately from each other on the substrate 130. The memory string 133 extends along the Z direction and penetrates the stacked structure 131. The stacked structure 131 may surround the memory strings 133. Each memory string 133 includes memory cells. In an embodiment, each memory string 133 can include memory cells disposed separately along the Z direction. The memory strings 133 can form the memory array 101. The memory array 101 is disposed between the substrate 130 and the first semiconductor structure 110W. The memory strings 133 can be AND type or NOR type or NAND type memory strings. The conductive layers 1311 of the stacked structure 131 are electrically connected to the memory cells of the memory strings 133. The conductive element 132 is disposed on the memory strings 133. The conductive element 132 is electrically connected to the memory strings 133. The memory strings 133 can be electrically connected to the interconnection structure 113 of the first semiconductor structure 110W through the conductive element 132. In an embodiment, each conductive layers 1311 can be functioned as a word line. In an embodiment, the conductive element 132 can include at least one bit line. In an embodiment, the conductive element 132 can include at least one conductive stripe and at least one interlayer connector, the conductive stripe and the interlayer connector include conductive materials, and the conductive stripe can be functioned as a bit line.

In an embodiment, each memory string 133 can include an insulating pillar, a channel layer surrounding the insulating pillar, and a memory layer surrounding the channel layer and the insulating pillar. The memory layer may include a multilayer structure. For example, the memory layer may include a tunnel layer on an outer sidewall of the channel layer, a storage layer on an outer sidewall of the tunnel layer, and a blocking layer on an outer sidewall of the storage layer. The memory layer may include a multilayer structure known from memory technologies, such as ONO (oxide-nitride-oxide), ONONO (oxide-nitride-oxide-nitride-oxide), ONONONO (oxide-nitride-oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), MA BE-SONOS (metal-high-k bandgap-engineered silicon-oxide-nitride-oxide-silicon), and combinations of those layers. The channel layer may include a semiconductor material, such as a doped or undoped polycrystalline silicon. The insulating pillar may include an insulating material such as silicon oxide. The memory cell can be defined in the memory layer at the intersection of the conductive layer 1311 and the memory string 133.

The stepped structure 141 and the plug elements 142 can be disposed in a peripheral region of the second semiconductor structure 120W. The peripheral region may be adjacent to the array region MR. The peripheral region may surround the array region MR. The stepped structure 141 is disposed on the substrate 130. The stepped structure 141 can be disposed on one side of the stacked structure 131. The stepped structure 141 includes conductive step layers 1411 and insulating step layers 1412 stacked alternately along the Z direction. The conductive step layers 1411 are separated from each other by the insulating step layers 1412. The conductive step layers 1411 and the insulating step layers 1412 can extend along the X direction and/or the Y direction. Each of the conductive step layers 1411 has different lateral area in the X-Y plane (a plane formed by the X direction and the Y direction). For example, the lateral area of the conductive step layer 1411 becomes smaller along the direction away from the substrate 130. For example, a conductive step layer 1411 at a lower level (a level closer to the substrate 130) has a lateral area larger than a lateral area that a conductive step layer 1411 at an upper level (a level farther from the substrate 130) has. The conductive step layer 1411 may include a conductive material, including but not limited to doped or undoped polycrystalline silicon, metal, or combinations thereof. The insulating step layer 1412 may include an insulating material, including but not limited to silicon oxide.

The conductive step layers 1411 of the stepped structure 141 can be electrically connected to the conductive layers 1311 of the stacked structure 131. In an embodiment, the conductive layers 1311 of the stacked structure 131 and the conductive step layers 1411 of the stepped structure 141 can have a one-to-one correspondence, that is, one conductive layer 1311 and one conductive step layer 1411 that corresponds to this conductive layer 1311 can have the same height (or level) in the Z direction.

The plug elements 142 are disposed on the conductive step layers 1411 of the stepped structure 141. Every plug element 142 can be disposed on a conductive step layer 1411 at different level. The plug element 142 is electrically connected to the conductive step layer 1411 where the plug element 142 is disposed, and electrically connected to a conductive layer 1311 located at the same level as the conductive step layer 1411. The conductive structure 143 is disposed on the plug elements 142. The conductive structure 143 can be electrically connected between the plug elements 142 and the interconnection structure 123. The plug elements 142 and the conductive structure 143 may include conductive materials.

The contact element 144 may extend along the Z direction and penetrate the substrate 130. The contact element 144 can be electrically connected to the via element 114, the pad 115 and the input/output pad 116 of the first semiconductor structure 110W. The contact element 144 can be electrically connected to the interconnection structure 123. The first peripheral circuit 103 can be electrically connected to the second peripheral circuit 105 through the contact element 144. The contact element 144 may include a conductive material.

In the embodiment shown in FIG. 5, the surface including the conductive element 132 and the contact element 144 can be defined as the functional surface of the second semiconductor structure 120W. Therefore, the first semiconductor structure 110W is bonded to the second semiconductor structure 120W in a face-to-face orientation. In an embodiment, signals can be transmitted between the memory cells of the memory strings 133 of the second semiconductor structure 120W, the conductive element 132 of the second semiconductor structure 120W, and the page buffer in the first peripheral circuit 103 of the first semiconductor structure 110W. In an embodiment, signals can be transmitted between the conductive layers 1311 of the second semiconductor structure 120W, the conductive step layers 1411 of the second semiconductor structure 120W, the plug elements 142 of the second semiconductor structure 120W, the conductive structure 143 of the second semiconductor structure 120W, and the row decoder in the second peripheral circuit 105 of the second semiconductor structure 120W. In the first semiconductor structure 110W, the power supply network and the signal network are provided on the functional surface of the first semiconductor structure 110W. The second semiconductor structure 120W can include a CMOS under array design.

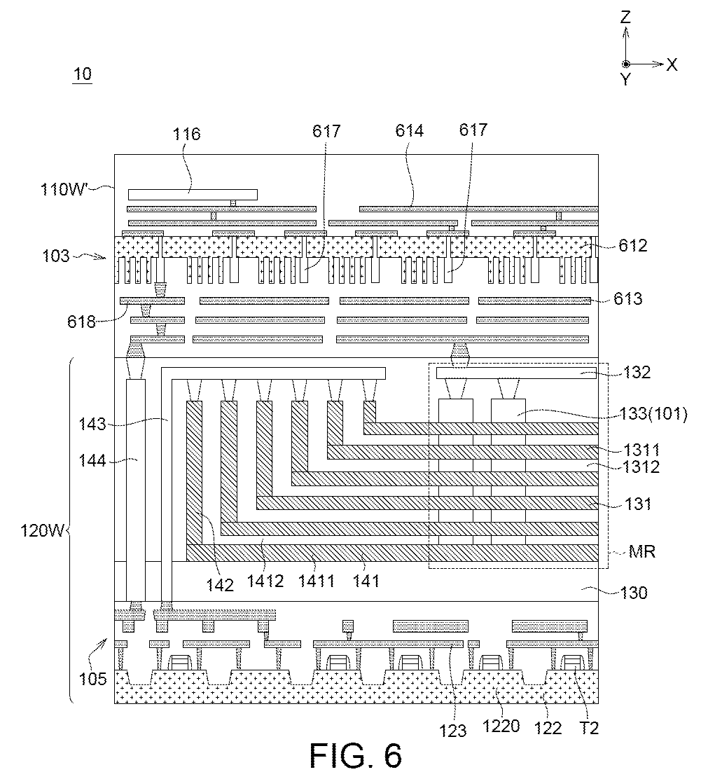

Referring to FIG. 6, FIG. 6 illustrates a schematic cross-sectional view showing one of the component configurations of the memory device 10 according to some embodiments of the present disclosure. The differences between the structure shown in FIG. 6 and the structure shown in FIG. 5 are that the structure of the first semiconductor structure 110W’ shown in FIG. 6 is different from the structure of the first semiconductor structure 110W shown in FIG. 5. The memory device 10 includes the first semiconductor structure 110W’ and the second semiconductor structure 120W. The first semiconductor structure 110W’ includes the first peripheral circuit 103. The first semiconductor structure 110W’ includes a device layer 612, a first interconnection structure 613, a second interconnection structure 614, via elements 617, a third interconnection structure 618, and an input/output pad 116. The device layer 612 includes a semiconductor material such as doped or undoped monocrystalline silicon, doped or undoped polycrystalline silicon, and germanium. The device layer 612 can include transistors such as fin field-effect transistors (FinFET) or complementary metal-oxide-semiconductor (CMOS) field-effect transistors. The first interconnection structure 613 and the second interconnection structure 614 are disposed on opposite sides of the device layer 612. The third interconnection structure 618 and the second interconnection structure 614 are disposed on opposite sides of the device layer 612. The first interconnection structure 613 and the third interconnection structure 618 are disposed on the same side of the device layer 612. The first interconnection structure 613 and the third interconnection structure 618 are disposed between the device layer 612 and the second semiconductor structure 120W. The second interconnection structure 614 is disposed between the device layer 612 and the input/output pad 116. The first interconnection structure 613 can be electrically connected to the transistors of the device layer 612. The first interconnection structure 613 can be electrically connected to the conductive element 132 and the memory strings 133 of the second semiconductor structure 120W. The via elements 617 penetrate the device layer 612. The via elements 617 can be electrically connected between the third interconnection structure 618 and the second interconnection structure 614. The input/output pad 116 can be electrically connected to the second interconnection structure 614. The input/output pad 116 can be electrically connected to the contact element 144 of the second semiconductor structure 120W through the second interconnection structure 614, the via elements 617 and the third interconnection structure 618. The first interconnection structure 613, the second interconnection structure 614, the via elements 617, the third interconnection structure 618 may include conductive materials. For example, the via element 617 can be a micro through silicon via (μTSV) element.

In the embodiment shown in FIG. 6, the surface including the first interconnection structure 613 and the third interconnection structure 618 can be defined as the functional surface of the first semiconductor structure 100W’, and the surface including the input/output pad 116 can be defined as the back surface of the first semiconductor structure 100W’. In the first semiconductor structure 110W’, the power supply network is provided on the back surface, which can improve power consumption and performance. The first semiconductor structure 110W’ includes a backside power delivery network (BSPDN). In the first semiconductor structure 110W’, the signal network is provided on the functional surface of the first semiconductor structure 110W’.

The device layer 612, the first interconnection structure 613, the second interconnection structure 614, the via element 617, the third interconnection structure 618 and the input/output pad 116 can form a portion of the first peripheral circuit 103; or alternatively, the first peripheral circuit 103 can include the device layer 612, the first interconnection structure 613, the second interconnection structure 614, the via element 617, the third interconnection structure 618 and the input/output pad 116. The input/output pad 116 can be a portion of the input/output circuit of the first peripheral circuit 103. The transistors of the device layer 612 can be electrically connected to the page buffer of the first peripheral circuit 103 or can be a portion of the page buffer of the first peripheral circuit 103. The input/output pad 116 can be used to receive a voltage such as voltage V_{DD} or voltage V_{SS}.

In the embodiment shown in FIG. 6, the first semiconductor structure 110W’ is bonded to the second semiconductor structure 120W in a face-to-face orientation. In an embodiment, signals can be transmitted between the memory cells of the memory strings 133 of the second semiconductor structure 120W, the conductive element 132 of the second semiconductor structure 120W and the page buffer in the first peripheral circuit 103 of the first semiconductor structure 110W’. In an embodiment, signals can be transmitted between the conductive layers 1311 of the second semiconductor structure 120W, the conductive step layers 1411 of the second semiconductor structure 120W, the plug elements 142 of the second semiconductor structure 120W, the conductive structure 143 of the second semiconductor structure 120W, and the row decoder in the second peripheral circuit 105 of the second semiconductor structure 120W.

In the embodiments shown in FIGS. 5 and 6, the second peripheral circuit 105 and the memory array 101 are disposed in the same semiconductor structure (wafer or chip), and the first peripheral circuit 103 and is disposed in another semiconductor structure (wafer or chip); such configuration can avoid damage to the first peripheral circuit caused by high-temperature process used to form the memory array. Since the high-voltage drive circuit of the second peripheral circuit has better temperature tolerance, the high-temperature process used to form the memory array will not cause damage to the second peripheral circuit. Therefore, providing the second peripheral circuit and the memory array in the same semiconductor structure can improve the overall performance of the memory device.

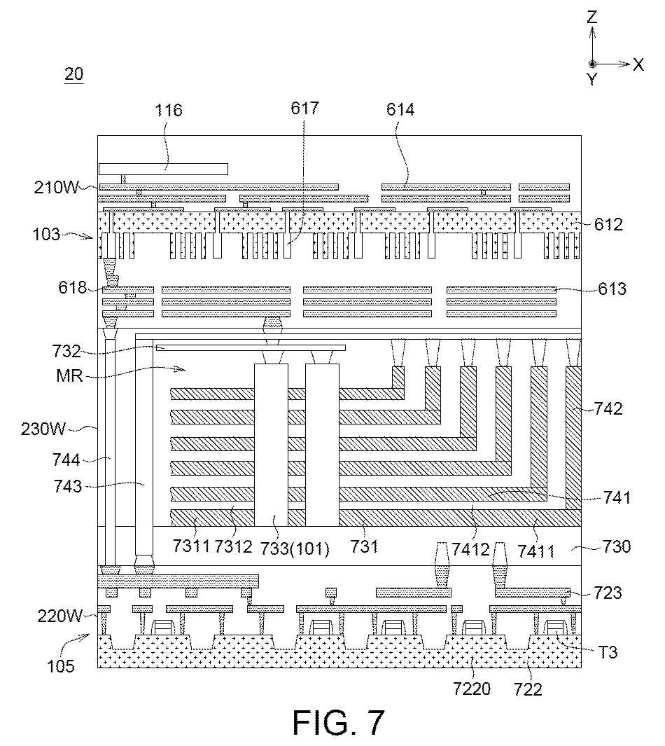

Referring to FIG. 7, FIG. 7 illustrates a schematic cross-sectional view showing one of the component configurations of the memory device 20 according to some embodiments of the present disclosure.

The memory device 20 includes a first semiconductor structure 210W, the second semiconductor structure 220W and a third semiconductor structure 230W. The first semiconductor structure 210W includes the first peripheral circuit 103. The first semiconductor structure 210W includes a device layer 612, a first interconnection structure 613, a second interconnection structure 614, via elements 617, a third interconnection structure 618, and an input/output pad 116. In the present embodiment, the first semiconductor structure 210W is similar to the first semiconductor structure 110W’, and configuration and descriptions of components in the first semiconductor structure 210W may refer to the descriptions related to the first semiconductor structure 110W’. The first interconnection structure 613 and the third interconnection structure 618 are disposed between the device layer 612 and the third semiconductor structure 230W. The second interconnection structure 614 is disposed between the device layer 612 and the input/output pad 116. The first interconnection structure 613 can be electrically connected to a conductive element 732 and memory strings 733 of the third semiconductor structure 230W. The input/output pad 116 can be electrically connected to a contact element 744 of the third semiconductor structure 230W through the second interconnection structure 614, the via elements 617 and the third interconnection structure 618.

The third semiconductor structure 230W include the memory array 101. The third semiconductor structure 230W includes a substrate 730, a stacked structure 731, the conductive element 732, the memory strings 733, a stepped structure 741, plug elements 742, a conductive structure 743 and the contact element 744. The substrate 730 may include a dielectric material. The stacked structure 731 and the memory strings 733 can be disposed in the array region MR of the third semiconductor structure 230W. The stacked structure 731 is disposed on the substrate 730. The stacked structure 731 can include conductive layers 7311 and insulating layers 7312 stacked alternately along the Z direction. The conductive layers 7311 are separated from each other by the insulating layers 7312. The conductive layers 7311 and the insulating layers 7312 can extend along the X direction and/or the Y direction. The conductive layer 7311 may include a conductive material, and the conductive material includes, but not limited to, doped or undoped polycrystalline silicon, metal, or combinations thereof. The insulating layer 7312 may include an insulating material, and the insulating material includes, but not limited to, silicon oxide. The memory strings 733 are disposed on the substrate 730. The memory strings 733 are disposed separately from each other on the substrate 730. The memory string 733 can extend along the Z direction and penetrates the stacked structure 731. The stacked structure 731 may surround the memory strings 733. Each memory string 733 includes memory cells. In an embodiment, each memory string 733 can include memory cells disposed separately along the Z direction. In an embodiment, the structure of the memory string 733 can be similar to the structure of the memory string 133. The memory strings 733 can form the memory array 101. The memory array 101 is disposed on the substrate 730. The memory array 101 is disposed between the substrate 730 and the first semiconductor structure 210W. The memory strings 733 can be AND type or NOR type or NAND type memory strings. The conductive layers 7311 of the stacked structure 731 are electrically connected to the memory cells of the memory strings 733. The conductive element 732 is disposed on the memory strings 733. The conductive element 732 is electrically connected to the memory strings 733. The memory strings 733 can be electrically connected to the interconnection structure 613 of the first semiconductor structure 210W through the conductive element 732. In an embodiment, each conductive layers 1311 can be functioned as a word line. In an embodiment, the conductive element 732 can include at least one bit line. In an embodiment, the conductive element 732 can include at least one conductive stripe and at least one interlayer connector, the conductive stripe and the interlayer connector include conductive materials, and the conductive stripe can be functioned as a bit line.

The stepped structure 741 and the plug elements 742 can be disposed in a peripheral region of the third semiconductor structure 230W. The peripheral region may be adjacent to the array region MR. The peripheral region may surround the array region MR. The stepped structure 741 is disposed on the substrate 730. The stepped structure 741 can be disposed on one side of the stacked structure 731. The stepped structure 741 includes conductive step layers 7411 and insulating step layers 7412 stacked alternately along the Z direction. The conductive step layers 7411 are separated from each other by the insulating step layers 7412. The conductive step layers 7411 and the insulating step layers 7412 can extend along the X direction and/or the Y direction. Each of the conductive step layers 7411 has different lateral area in the X-Y plane. For example, the lateral area of the conductive step layer 7411 becomes smaller along the direction away from the substrate 730. For example, a conductive step layer 7411 at a lower level (a level closer to the substrate 730) has a lateral area larger than a lateral area that a conductive step layer 7411 at an upper level (a level farther from the substrate 730) has. The conductive step layer 7411 may include a conductive material, including but not limited to doped or undoped polycrystalline silicon, metal, or combinations thereof. The insulating step layer 7412 may include an insulating material, including but not limited to silicon oxide.

The conductive step layers 7411 of the stepped structure 741 can be electrically connected to the conductive layers 7311 of the stacked structure 731. In an embodiment, the conductive layers 7311 of the stacked structure 731 and the conductive step layers 7411 of the stepped structure 741 can have a one-to-one correspondence, that is, one conductive layer 7311 and one conductive step layer 7411 that corresponds to this conductive layer 7311 can have the same height (or level) in the Z direction.

The plug elements 742 are disposed on the substrate 730. The plug elements 742 are disposed on the conductive step layers 7411 of the stepped structure 741. Every plug element 742 can be disposed on a conductive step layer 7411 at different level. The plug element 742 is electrically connected to the conductive step layer 7411 where the plug element 742 is disposed, and electrically connected to a conductive layer 7311 located at the same level as the conductive step layer 7411. The conductive structure 743 is disposed on the plug elements 742. The conductive structure 743 penetrates the substrate 730. The conductive structure 743 can be electrically connected between the plug elements 742 and an interconnection structure 723 of the semiconductor structure 220W. The word lines of the memory device 20 can be electrically to the second semiconductor structure 220W through the plug elements 742 and the conductive structure 743. The plug elements 742 and the conductive structure 743 may include conductive materials. The contact element 744 may extend along the Z direction and penetrate the substrate 730. The contact element 744 can be electrically connected to the interconnection structure 723 of the second semiconductor structure 220W. The contact element 744 may include a conductive material.

The semiconductor structure 220W includes the second peripheral circuit 105. The semiconductor structure 220W includes a device layer 722 and the interconnection structure 723. The device layer 722 includes a semiconductor layer 7220 and transistors T3. The semiconductor layer 7220 may include a semiconductor material such as doped or undoped monocrystalline silicon, doped or undoped polycrystalline silicon, and germanium. FIG. 7 shows that the transistor T3 is on the surface of the semiconductor layer 7220, but the present disclosure is not limited thereto. The transistor T3 can be disposed near the surface of the semiconductor layer 7220, that is, the transistor T3 may be completely disposed above the surface of the semiconductor layer 7220; or alternatively, a portion of the transistor T3 (e.g. the gate structure) may be disposed above the surface of the semiconductor layer 7220, and another portion of the transistor T3 (e.g. the drain structure and/or source structure) may be disposed under the surface of the semiconductor layer 7220 and in the semiconductor layer 7220; or alternatively, the transistor T3 may be completely disposed in the semiconductor layer 7220. The interconnection structure 723 is disposed on the semiconductor layer 7220. The transistors T3 can be electrically connected to the interconnection structure 723. The interconnection structure 723 may include a conductive material. The device layer 722 and the interconnection structure 723 can form a portion of the second peripheral circuit 105; or alternatively, the second peripheral circuit 105 can include the device layer 722 and the interconnection structure 723. The transistors T3 can be electrically connected to the charge pumping circuit and the row decoder of the second peripheral circuit 105. In an embodiment, the transistors T3 can be a complementary metal-oxide-semiconductor field-effect transistor.

In the embodiment shown in FIG. 7, the surface including the first interconnection structure 613 and the third interconnection structure 618 can be defined as the functional surface of the first semiconductor structure 210W, and the surface including the input/output pad 116 can be defined as the back surface of the first semiconductor structure 210W. In the first semiconductor structure 210W, the power supply network is provided on the back surface, which can improve power consumption and performance. The first semiconductor structure 210W includes a backside power delivery network (BSPDN). In the first semiconductor structure 210W, the signal network is provided on the functional surface of the first semiconductor structure 210W. In the embodiment shown in FIG. 7, the surface including the conductive element 732 and the contact element 744 can be defined as the functional surface of the third semiconductor structure 230W, and the surface of the substrate 730 that is not used to dispose the memory strings 733 can be defined as the back surface of the third semiconductor structure 230W. The surface including the interconnection structure 723 can be defined as the functional surface of the second semiconductor structure 220W. Therefore, the first semiconductor structure 210W is bonded to the third semiconductor structure 230W in a face-to-face orientation, and the second semiconductor structure 220W is bonded to the third semiconductor structure 230W in a face-to-back orientation. In an embodiment, signals can be transmitted between the memory cells of the memory strings 733 of the third semiconductor structure 230W, the conductive element 732 of the third semiconductor structure 230W and the page buffer in the first peripheral circuit 103 of the first semiconductor structure 210W. In an embodiment, signals can be transmitted between the conductive layers 7311 of the third semiconductor structure 230W, the conductive step layers 7411 of the third semiconductor structure 230W, the plug elements 742 of the third semiconductor structure 230W, the conductive structure 743 of the third semiconductor structure 230W, and the row decoder in the second peripheral circuit 105 of the second semiconductor structure 220W.

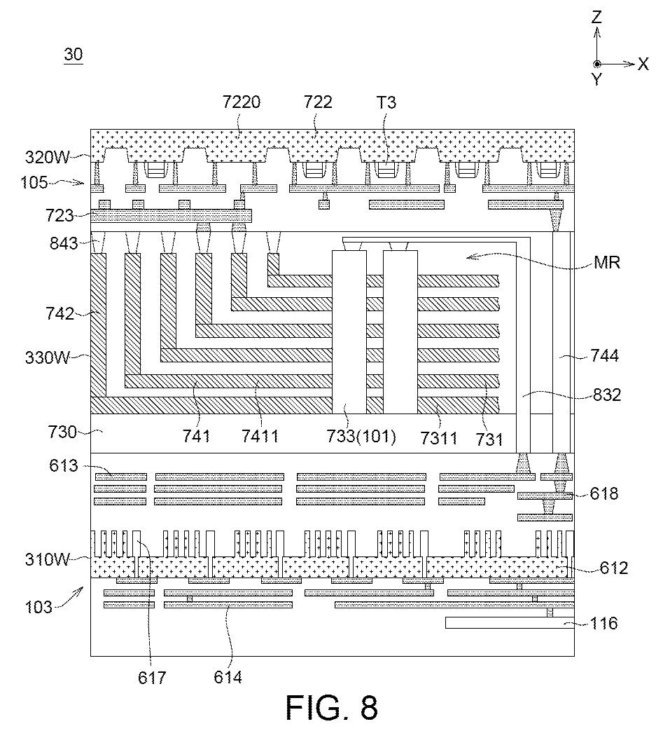

Referring to FIG. 8, FIG. 8 illustrates a schematic cross-sectional view showing one of the component configurations of the memory device 30 according to some embodiments of the present disclosure.

The memory device 30 includes a first semiconductor structure 310W, the second semiconductor structure 320W and a third semiconductor structure 330W. The first semiconductor structure 310W includes the first peripheral circuit 103. The first semiconductor structure 310W includes a device layer 612, a first interconnection structure 613, a second interconnection structure 614, via elements 617, a third interconnection structure 618, and an input/output pad 116. In the present embodiment, the first semiconductor structure 310W is similar to the first semiconductor structure 110W’ and the first semiconductor structure 210W, and configuration and descriptions of components in the first semiconductor structure 310W may refer to the descriptions related to the first semiconductor structure 110W’ and the first semiconductor structure 210W. The first interconnection structure 613 and the third interconnection structure 618 are disposed between the device layer 612 and the third semiconductor structure 330W. The second interconnection structure 614 is disposed between the device layer 612 and the input/output pad 116. The first interconnection structure 613 can be electrically connected to a conductive element 832 and memory strings 733 of the third semiconductor structure 330W. The input/output pad 116 can be electrically connected to a contact element 744 of the third semiconductor structure 330W through the second interconnection structure 614, the via elements 617 and the third interconnection structure 618.

The third semiconductor structure 330W include the memory array 101. The third semiconductor structure 330W includes a substrate 730, a stacked structure 731, the conductive element 832, the memory strings 733, a stepped structure 741, plug elements 742, a conductive structure 843 and the contact element 744. The stacked structure 731 and the memory strings 733 can be disposed in the array region MR of the third semiconductor structure 330W. The memory array 101 is disposed between the substrate 730 and the second semiconductor structure 320. The conductive element 832 is disposed on the memory strings 733. The conductive element 832 can penetrate the substrate 730. The conductive element 832 is electrically connected to the memory strings 733. The memory array 101 (or the memory strings 733) can be electrically connected to the interconnection structure 613 of the first semiconductor structure 310W through the conductive element 832. In an embodiment, the conductive element 832 can include at least one bit line. In an embodiment, the conductive element 832 can include at least one conductive stripe and at least one interlayer connector, the conductive stripe and the interlayer connector include conductive materials, and the conductive stripe can be functioned as a bit line. The conductive element 832 shown in FIG. 8 can extend beyond the lower surface of the stacked structure 731 and the lower surfaces of the memory strings 733 and penetrate the substrate 730 to be electrically connected to the interconnection structure 613 of the first semiconductor structure 310W below the third semiconductor structure 330W.

The stepped structure 741 and the plug elements 742 can be disposed in a peripheral region of the third semiconductor structure 330W. The peripheral region may be adjacent to the array region MR. The peripheral region may surround the array region MR. The stepped structure 741 is disposed on the substrate 730. The stepped structure 741 can be disposed on one side of the stacked structure 731. The conductive step layers 7411 of the stepped structure 741 can be electrically connected to the conductive layers 7311 of the stacked structure 731. The plug element 742 is electrically connected to the conductive step layer 7411 where the plug element 742 is disposed, and electrically connected to a conductive layer 7311 located at the same level as the conductive step layer 7411. The conductive structure 843 is disposed on the plug elements 742. The conductive structure 843 can be electrically connected between the plug elements 742 and the interconnection structure 723 of the second semiconductor structure 320W. The contact element 744 may extend along the Z direction and penetrate the substrate 730. The contact element 744 can be electrically connected to the interconnection structure 723 of the second semiconductor structure 320W. The contact element 744 can be electrically connected to the third interconnection structure 618 of the first semiconductor structure 310W.

The semiconductor structure 320W includes the second peripheral circuit 105. The semiconductor structure 320W includes a device layer 722 and the interconnection structure 723. The device layer 722 includes a semiconductor layer 7220 and transistors T3. FIG. 8 shows that the transistor T3 is on the surface of the semiconductor layer 7220, but the present disclosure is not limited thereto. The transistor T3 can be disposed near the surface of the semiconductor layer 7220, that is, the transistor T3 may be completely disposed above the surface of the semiconductor layer 7220; or alternatively, a portion of the transistor T3 (e.g. the gate structure) may be disposed above the surface of the semiconductor layer 7220, and another portion of the transistor T3 (e.g. the drain structure and/or source structure) may be disposed under the surface of the semiconductor layer 7220 and in the semiconductor layer 7220; or alternatively, the transistor T3 may be completely disposed in the semiconductor layer 7220. The interconnection structure 723 is disposed on the semiconductor layer 7220. The interconnection structure 723 can be disposed between the semiconductor layer 7220 and the third semiconductor structure 330W. The transistors T3 can be electrically connected to the interconnection structure 723. The device layer 722 and the interconnection structure 723 can form a portion of the second peripheral circuit 105; or alternatively, the second peripheral circuit 105 can include the device layer 722 and the interconnection structure 723. The transistors T3 can be electrically connected to the charge pumping circuit and the row decoder of the second peripheral circuit 105.

In the embodiment shown in FIG. 8, the surface including the first interconnection structure 613 and the third interconnection structure 618 can be defined as the functional surface of the first semiconductor structure 310W, and the surface including the input/output pad 116 can be defined as the back surface of the first semiconductor structure 310W. In the first semiconductor structure 310W, the power supply network is provided on the back surface, which can improve power consumption and performance. The first semiconductor structure 310W includes a backside power delivery network (BSPDN). In the first semiconductor structure 310W, the signal network is provided on the functional surface of the first semiconductor structure 310W. In the embodiment shown in FIG. 8, the surface including the conductive structure 843 and the contact element 744 can be defined as the functional surface of the third semiconductor structure 330W, and the surface of the substrate 730 that is not used to dispose the memory strings 733 can be defined as the back surface of the third semiconductor structure 330W. In the embodiment shown in FIG. 8, the surface including the interconnection structure 723 can be defined as the functional surface of the second semiconductor structure 320W. Therefore, the third semiconductor structure 330W is bonded to the second semiconductor structure 320W in a face-to-face orientation, and the first semiconductor structure 310W is bonded to the third semiconductor structure 330W in a face-to-back orientation. In an embodiment, signals can be transmitted between the memory cells of the memory strings 733 of the third semiconductor structure 330W, the conductive element 832 of the third semiconductor structure 330W and the page buffer in the first peripheral circuit 103 of the first semiconductor structure 310W. In an embodiment, signals can be transmitted between the conductive layers 7311 of the third semiconductor structure 330W, the conductive step layers 7411 of the third semiconductor structure 330W, the plug elements 742 of the third semiconductor structure 330W, the conductive structure 843 of the third semiconductor structure 330W, and the row decoder in the second peripheral circuit 105 of the second semiconductor structure 320W.

In an embodiment, the memory device according to the present disclosure can include 32 or more than 32 planes, each plane can include blocks, and each block can include pages including memory cells. In an embodiment, the memory device according to the present disclosure can include 32 or more than 32 IO (i.e. 32 or more than 32 data paths); for example, the memory device according to the present disclosure can include 1024 IO.

The present disclosure provides peripheral circuit systems of memory devices and a memory devices including the peripheral circuit systems and the memory arrays. In the present disclosure, a portion of the peripheral circuit system (first peripheral circuit) and another portion of the peripheral circuit system (second peripheral circuit) are arranged along a longitudinal direction, which can increase the footprint of peripheral circuit system without increasing the area (area in the lateral direction) of the memory device, and can improve the performance, endurance, power consumption and reliability of the memory device while taking into account the needs of area shrinkage of memory device.

It is noted that the structures as described above are provided for illustration. The disclosure is not limited to the configurations disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a memory device, the shapes or positional relationship of the elements could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A peripheral circuit system of a memory device, comprising:
a first peripheral circuit electrically connected to a memory array of the memory device; and
a second peripheral circuit electrically connected to the memory array,
wherein the first peripheral circuit and the second peripheral circuit are arranged along a longitudinal direction.

2. The peripheral circuit system according to claim 1, wherein the second peripheral circuit comprises at least one charge pumping circuit and at least one row decoder.

3. The peripheral circuit system according to claim 1, wherein the first peripheral circuit comprises at least one page buffer and at least one input/output circuit.

4. The peripheral circuit system according to claim 1, wherein the first peripheral circuit and the second peripheral circuit are disposed on opposite sides of the memory array.

5. The peripheral circuit system according to claim 1, wherein the first peripheral circuit and the second peripheral circuit are disposed on the same side of the memory array.

6. The peripheral circuit system according to claim 1, wherein the first peripheral circuit is disposed in a first semiconductor structure, the second peripheral circuit is disposed in a second semiconductor structure, the first semiconductor structure and the second semiconductor structure are stacked along the longitudinal direction, the first semiconductor structure are hybrid bonded to the second semiconductor structure.

7. A memory device, comprising:
a first semiconductor structure comprising a first peripheral circuit; and
a second semiconductor structure comprising a second peripheral circuit and a memory array,
wherein the first semiconductor structure is bonded to the second semiconductor structure, the first peripheral circuit is electrically connected to the memory array, and the second peripheral circuit is electrically connected to the memory array.

8. The memory device according to claim 7, wherein the first peripheral circuit and the second peripheral circuit are disposed on opposite sides of the memory array.

9. The memory device according to claim 7, wherein the first peripheral circuit comprises at least one page buffer and at least one input/output circuit, and the second peripheral circuit comprises at least one charge pumping circuit and at least one row decoder.

10. The memory device according to claim 7, wherein the second semiconductor structure comprises a substrate and a contact element, the second peripheral circuit is disposed on a first of the substrate, the memory array is disposed on a second side of the substrate and between the substrate and the first semiconductor structure, the first side is opposite to the second side, the first peripheral circuit is electrically connected to the second peripheral circuit through the contact element.

11. The memory device according to claim 10, wherein the first semiconductor structure comprises a device layer, a first interconnection structure, a second interconnection structure, a via element, a third interconnection structure, and an input/output pad, the first interconnection structure and the second interconnection structure are disposed on opposite sides of the device layer, the second interconnection structure is between the input/out pad and the device layer, the first interconnection structure and the third interconnection structure are disposed between the device layer and the second semiconductor structure, and the via element penetrates the device layer.

12. The memory device according to claim 11, wherein the input/output pad is electrically connected to the semiconductor structure through the second interconnection structure, the via element and the third interconnection structure.

13. A memory device, comprising:
a first semiconductor structure comprising a first peripheral circuit;
a second semiconductor structure comprising a second peripheral circuit; and
a third semiconductor structure comprising a memory array,
wherein the first semiconductor structure, the second semiconductor structure, and the third semiconductor structure are arranged along a longitudinal direction, the first peripheral circuit is electrically connected to the memory array, and the second peripheral circuit is electrically connected to the memory array.

14. The memory device according to claim 13, wherein the third semiconductor structure is disposed between the first semiconductor structure and the second semiconductor structure in a longitudinal direction.

15. The memory device according to claim 13, wherein the first peripheral circuit comprises at least one page buffer and at least one input/output circuit, and the second peripheral circuit comprises at least one charge pumping circuit and at least one row decoder.

16. The memory device according to claim 15, wherein the first semiconductor structure is bonded to the third semiconductor structure in a face-to-face orientation, and the second semiconductor structure is bonded to the third semiconductor structure in a face-to-back orientation.

17. The memory device according to claim 15, wherein the second semiconductor structure is bonded to the third semiconductor structure in a face-to-face orientation, the first semiconductor structure is bonded to the third semiconductor structure in a face-to-back orientation.

18. The memory device according to claim 13, wherein the third semiconductor structure comprises a substrate, a word line, a plug element and a conductive structure, the word line, the plug element and the memory array is on the substrate, the conductive structure penetrates the substrate, and the word line is electrically connected to the second semiconductor structure through the plug element and the conductive structure.

19. The memory device according to claim 13, wherein the third semiconductor structure comprises a substrate and a conductive element, the memory array is on the substrate, the conductive element penetrates the substrate, the memory array is electrically connected to the first semiconductor structure through the conductive element.

20. The memory device according to claim 13, wherein the first semiconductor structure is arranged between the third semiconductor structure and the second semiconductor structure along a longitudinal direction.
* * * * *
